(19) United States
(12) Patent Application Publication
(10) Pub. No.: US 2014/0102537 A1
(43) Pub. Date: Apr. 17, 2014

(54) PHOTOVOLTAIC MODULE

(71) Applicant: First Solar, Inc., Perrysburg, OH (US)

(72) Inventor: Richard S Malik, JR., Rossford, OH (US)

(73) Assignee: First Solar, Inc., Perrysburg, OH (US)

(21) Appl. No.: 14/054,154

(22) Filed: Oct. 15, 2013

Related U.S. Application Data
(60) Provisional application No. 61/713,789, filed on Oct. 15, 2012.

(51) Int. Cl. H01L 31/048

(52) U.S. Cl. CPC H01L 31/048
USPC 136/259; 156/60; 156/185

(57) ABSTRACT

A layer for use in a photovoltaic module may include an interlayer and one or more corrosion barriers adjacent to an electrically conductive layer.

### CLAIM OF PRIORITY

This application claims priority under 35 U.S.C. §119(e) to U.S. Provisional Patent Application Ser. No. 61/713,789 filed on Oct. 15, 2012, which is hereby incorporated by reference in its entirety.

### TECHNICAL FIELD

The present invention relates to interlayers with one or more corrosion barriers, photovoltaic (PV) modules with interlayers, and methods for manufacturing interlayers for PV modules.

### BACKGROUND

A PV device converts light to electricity and a plurality of PV devices or cells may be formed on a common substrate to produce a PV module. During light exposure, current flows through a circuit connected to a front and back contact layer of the module. The circuit may include thin portions of electrically conductive material that allow for current transmission as well as production of a thin module. Over time, chemical interactions within the module may cause corrosion on the portions of conductive material, thereby degrading the module's appearance and performance.

### DESCRIPTION OF DRAWINGS

FIG. 1 is a top perspective view of a PV module.

FIG. 2 is a bottom perspective view of a PV module.

FIG. 3 is a cross-sectional view of FIG. 1 taken along section A-A.

FIG. 4A is a bottom perspective view of a partially assembled PV module prior to installation of the interlayer according to a first embodiment.

FIG. 4B is a bottom perspective view of a partially assembled PV module prior to installation of the interlayer according to a second embodiment.

FIG. 4C is a bottom perspective view of a partially assembled PV module prior to installation of the interlayer according to a third embodiment.

FIG. 5 is a cross-sectional view of the PV module of FIG. 4A taken along section B-B.

FIG. 6A is an exploded view of a partially assembled PV module with an interlayer, a back cover, and a cord plate according to a first embodiment.

FIG. 6B is an exploded view of a partially assembled PV module with an interlayer, a back cover, and a cord plate according to a second embodiment.

FIG. 6C is an exploded view of a partially assembled PV module with an interlayer, a back cover, and a cord plate according to a third embodiment.

FIG. 7A is a bottom perspective view of a partially assembled PV module prior to installation of the interlayer from a roll according to a first embodiment.

FIG. 7B is a bottom perspective view of a partially assembled PV module prior to installation of the interlayer from a roll according to a second embodiment.

FIG. 7C is a bottom perspective view of a partially assembled PV module prior to installation of the interlayer from a roll according to a third embodiment.

FIG. 8A is a partially assembled PV module during formation of an interlayer with integrated barrier tape in sheet form according to a first embodiment.

FIG. 8B is a partially assembled PV module during formation of an interlayer with integrated barrier tape in sheet form according to a second embodiment.

FIG. 8C is a partially assembled PV module during formation of an interlayer with integrated barrier tape in sheet form according to a third embodiment.

FIG. 9A is a partially completed PV module during formation of an interlayer with integrated barrier tape from a roll according to a first embodiment.

FIG. 9B is a partially completed PV module during formation of an interlayer with integrated barrier tape from a roll according to a second embodiment.

FIG. 9C is a partially completed PV module during formation of an interlayer with integrated barrier tape from a roll according to a third embodiment.

### DETAILED DESCRIPTION

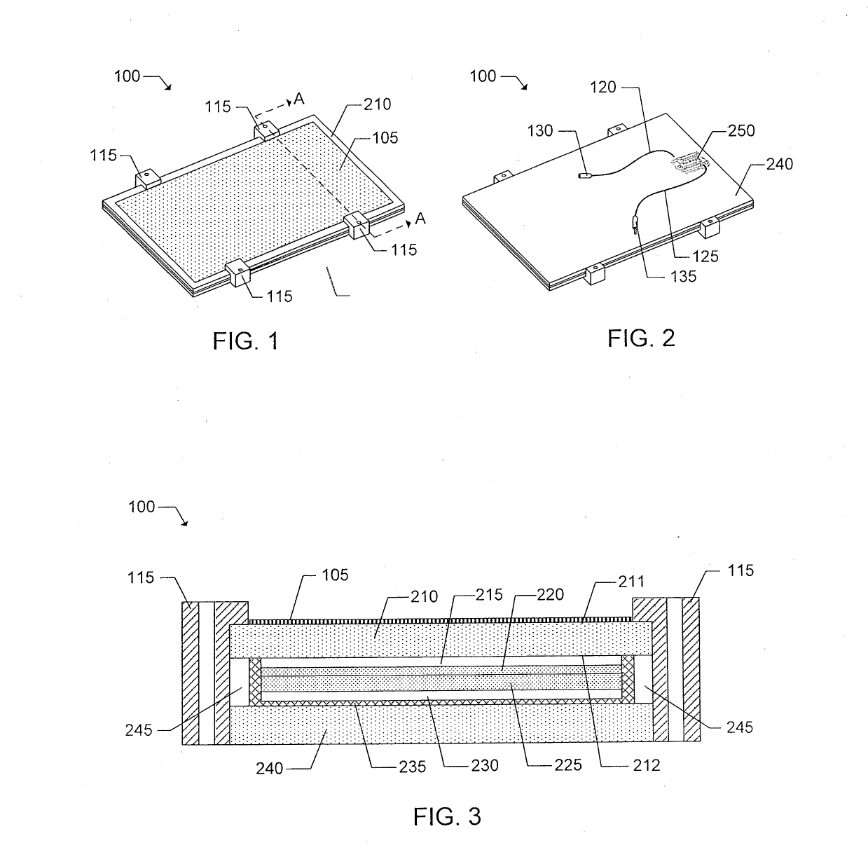

A PV module converts light to electricity and may include multiple layers created on a substrate. In general, FIGS. 1 and 2 show a top and a bottom perspective view of an exemplary PV module 100, respectively. To permit interconnection to other electrical devices, the module 100 may include a junction box 250, which may be referred to as a cord plate. A first and second cable (120, 125) having a first and second connector (130, 135), respectively, may extend from the junction box 250 and may allow for easy connection to other modules in a PV array. The module 100 may be fastened to the array through a plurality of mounting brackets 115.

FIG. 3 shows a side cross-sectional view of the module 100 of FIG. 1 taken along section A-A thereby exposing one PV cell within the module 100. The various layers of the PV cell are visible in FIG. 3.

As shown by way of example in FIG. 3, the module 100 may include a substrate layer 210. The substrate layer 210 may be the outermost layer of the module 100 and may be exposed to a variety of temperatures and types of precipitation during the life of the module 100. The substrate layer 210 may also be the first layer that incident light encounters upon entering the module. Therefore, it is desirable to select a material that is both durable and highly transparent. For these reasons, the substrate layer 210 may include, for example, glass. In particular, it may be desirable to select a type of glass having low iron content since it provides greater light transmission than glasses containing standard amounts of iron. Examples of suitable glass types include borosilicate glass, soda lime glass, and float glass.

The substrate layer 210 may include an outer surface 211 and an inner surface 212. The substrate layer 210 may include an anti-reflective (AR) coating 105 adjacent to the outer surface 211 to increase light transmittance.

A front contact layer 215, which may serve as a first electrode for the module 100, may include a stack of layers adjacent to the inner surface 212 of the substrate layer 210. To provide a front contact layer 215 for the module 100, a conductive layer is formed adjacent to the inner surface 212 of the substrate layer 210. The front contact layer 215 may include a stack of layers. The stack of layers, which are referred to as a transparent conductive oxide (TCO) stack, can include a barrier layer, a TCO layer, and a buffer layer. These layers can be formed sequentially on the inner surface of the substrate 210. Alternatively, the front contact layer 215 can be formed in a series of manufacturing steps separate from the module 100 and added to the module 100 in a single step.

A semiconductor window layer 220, which can be an n-type semiconductor such as cadmium sulfide (CdS), may be formed adjacent to the front contact layer 215. A semiconductor absorber layer 225 may be formed adjacent to the semiconductor window layer 220. The semiconductor absorber layer 225 may be a p-type semiconductor and may include any suitable material such as, for example, cadmium telluride (CdTe), cadmium selenide, amorphous silicon, copper indium (di)selenide (CIS), or copper indium gallium (di)selenide (CIGS). Having the n-type semiconductor window layer 220 in close contact to the p-type semiconductor absorber layer 225 forms a p-n junction, which facilitates conversion of light to electricity.

A p-n junction may be formed where the semiconductor absorber layer 225 abuts the semiconductor window layer 220. When the PV module 100 is exposed to sunlight, photons may be absorbed within the p-n junction region. As a result, photo-generated electron-hole pairs may be created. Movement of the electron-hole pairs may be promoted by a built-in electric field, thereby producing current. Current may flow between a first cable 120 connected to the front contact layer 215 and a second cable 125 connected to a back contact layer 230. The first and second leads (120, 125) may extend from the junction box 250 as discussed above and as shown in FIG. 2.

The back contact layer 230, which may serve as a second electrode to the module 100, may be formed adjacent to the semiconductor absorber layer 225. The back contact layer 230 may include one or more highly conductive materials. For example, the back contact layer 230 may include molybdenum, aluminum, copper, silver, gold, or any combination thereof.

An interlayer 235 may be formed adjacent to the back contact layer 230. The interlayer 235 may be formed through a lamination process or any other suitable formation technique. The interlayer 235 may serve as a waterproof, electrically insulating barrier that protects the plurality of PV cells within the module from moisture-related corrosion. The interlayer 235 may include any suitable electrically insulating material such as, for example, a thermoplastic copolymer resin such as ethylene vinyl acetate (EVA), polyvinyl butyral (PVB), or thermoplastic polyurethane (TPU). Interlayer 235 can include materials that are not water soluble to protect the interior of the PV module 100 from rain and other elements.

To further protect the module 100 from moisture ingress, an edge sealant 245 may be added around the perimeter of the module 100 and may include any suitable material such as butyl rubber. The edge sealant 245 may also serve as an adhesive that bonds the substrate 210 to a back cover 240. The back cover 240 may include a transparent protective material such as borosilicate glass, float glass, soda lime glass, or polycarbonate. Alternatively, if the substrate layer 210 is the first layer that incident light encounters upon entering a PV module, as in module 100, the back cover 240 may include any suitable non-transparent material such as Coveme's APYE or 3M's polymer back sheet.

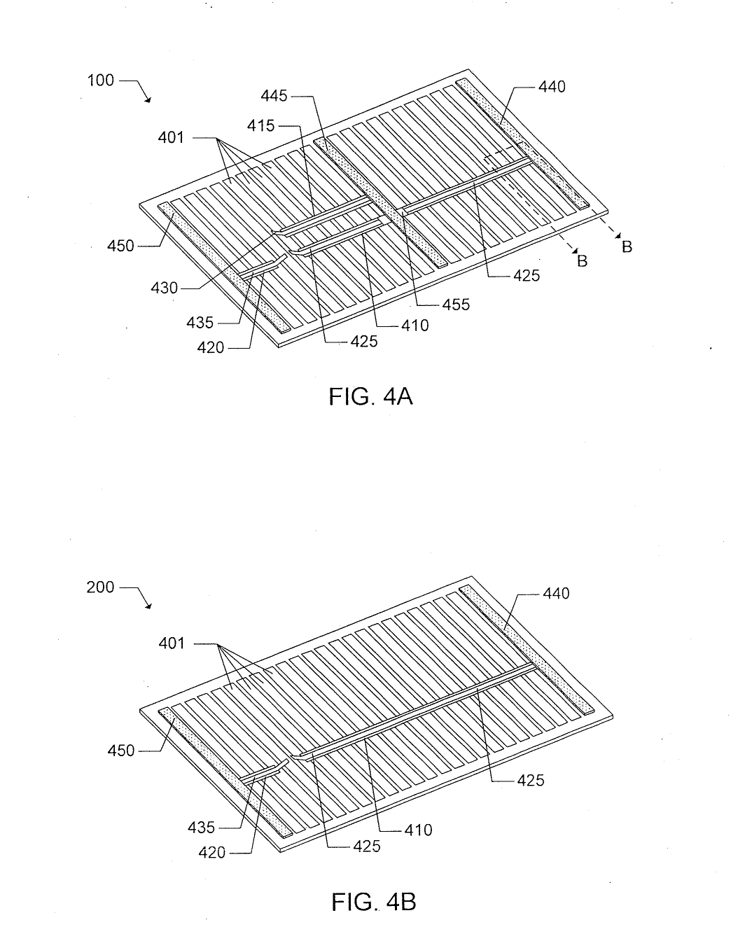

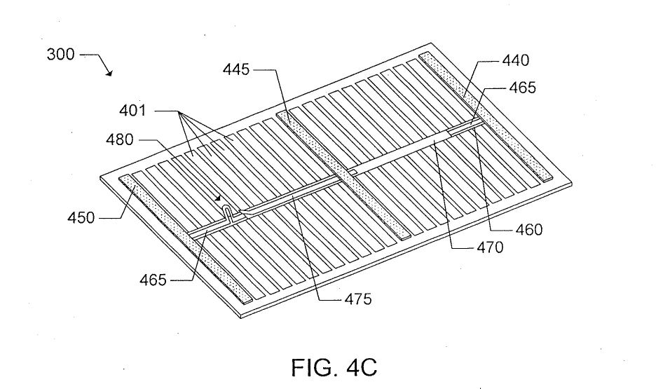

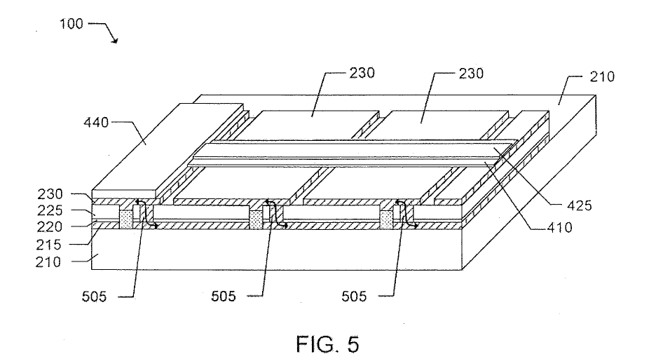

As shown by way of example in FIG. 4A, a partially assembled PV module 100 (shown from a bottom perspective view) may include a plurality of PV cells 401 formed adjacent to the substrate layer 210. FIG. 5 shows a cross sectional view of module 100 of FIG. 4A taken along section B-B. As shown by way of example in FIG. 5, adjacent cells can be electrically connected via electrical interconnects 505. The interconnects 505 can be formed through a combination of scribing and deposition steps, where scribing involves material removal and deposition involves material addition.

During the scribing and deposition process, adjacent cells may be interconnected in series or in parallel. In some instances, all cells in the module 100 may be connected in series. In other cases it may be desirable to subdivide the module 100 into two or more sub-modules. Subdivision of the module can be accomplished by omitting an interconnect 505 between two adjacent cells and inserting a nonconductive material, such as photoresist, in place of the interconnect 505. FIGS. 4A and 4C show examples of modules 100, 300 divided into two sub-modules.

Once the module 100 has been divided into sub-modules, a series of steps may be used to electrically connect the sub-modules in parallel, for example. The sub-modules may be electrically connected through a lay-up process to produce a module that resembles the module 100 shown in FIG. 4A. As described in co-pending U.S. patent application Ser. No. 12/334,028, incorporated herein by reference in its entirety, the lay-up process may involve forming two sub-modules to share a contact to the front contact layer 215 on the substrate 210 through a shared PV cell, e.g., typically the last cell in a series.

FIGS. 4A-4C respectively show a bottom perspective of PV modules 100, 200, 300 prior to installation of the interlayer 235 and back cover 240. The back contact layer 230 of each cell is visible as well as various portions of insulating tape (410, 415, 420, 455, 460, 470), various portions of conductive tape (425, 430, 435, 465, 475), and bus bars (440, 445, 450), collectively referred to as a bussing system.

As shown in FIG. 4A, once the back contact layer 230 has been formed, one or more portions of insulating tape may be formed adjacent to the back contact layer 230. For example, a first portion of insulating tape 410, a second portion of insulating tape 415, and a third portion of insulating tape 420, may be formed adjacent to the back contact layer 230. A fourth portion of insulating tape 455 may be formed adjacent to bus bar 445, as discussed below. The portions of insulating tape (410, 415, 420, 455) may be constructed from any suitable electrically insulating material. The portions of insulating tape (410, 415, 420, 455) may each have a first side and a second side, and the first and second sides of each portion may include an adhesive coating similar to double-sided tape. For example, the portions of insulating tape may be 3M Double Coated Dielectric Tape 3514, 3M Double Coated Tape 9500PC, or other similar product.

One or more portions of a conductive tape may be formed adjacent to the portions of insulating tape 410, 415, and 420. For example, a first portion of conductive tape 425 may be placed adjacent to the first portion of insulating tape 410, a second portion of conductive tape 430 may be placed adjacent to the second portion of insulating tape 415, a third portion of conductive tape 435 may be placed adjacent to the third portion of insulating tape 420, and the fourth portion of insulating tape 455 may be formed between the first portion of conductive tape 425 and bus bar 445. The portions of conductive tape 425, 430, and 435 can be constructed from one or more conductive materials suitable for transferring electrical current. For example, the portions of conductive tape may include tin, copper, aluminum, silver, gold, or any other suitable conductive material. The portions of conductive tape may include tin-plated copper.

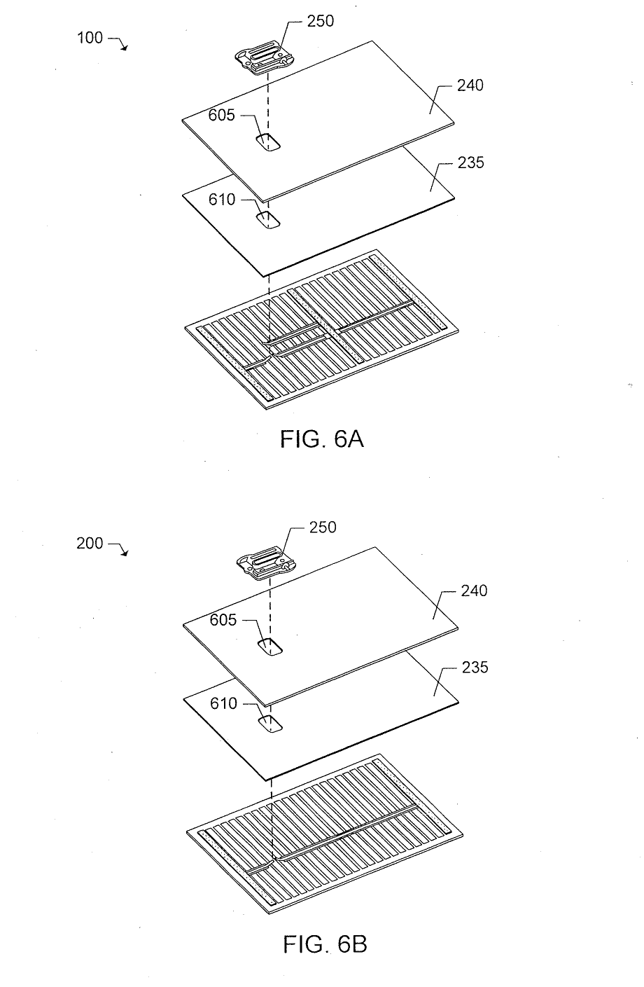

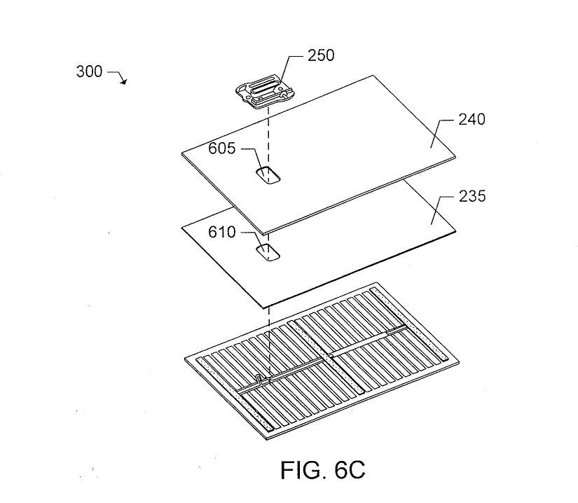

FIG. 4B shows a module 200 that is similar to module 100 of FIG. 4A except that module 200 does not have bus bar 445, insulating tape 415, 455 or conductive tape 430 such that the free ends of the first and third portions of conductive tape 425, 435 may be located proximate to an opening 605 in the back cover 240 and an opening 610 in the interlayer 235, as illustrated in FIG. 6B and discussed below.

FIG. 4C illustrates a module 300 that is similar to module 100 of FIG. 4A except that, instead of portions of insulating tape (410, 415, 420, 455) and conductive tape (425, 430, 435), a fifth portion of insulating tape 460 may be formed adjacent to the back contact layer 230 and a fourth portion of conductive tape 465 may be formed adjacent to the fifth portion of insulating tape 460. A part of the forth portion of conductive tape 465 may form a loop 480. A sixth portion of insulating tape 470 may be formed adjacent to conductive tape 465 and a fifth portion of conductive tape 475 may be formed adjacent to the sixth portion of insulating tape 470. The free end of the fifth portion of conductive tape 475 and the loop 480 may be located proximate to an opening 605 in the back cover 240 and an opening 610 in the interlayer 235, as illustrated in FIG. 6C and discussed below.

As shown by way of example in FIGS. 6A-6C, each portion of conductive tape (425, 430, 435, 475) may have a free end that is not connected to any portion of insulating tape. The free ends and loop 480 of conductive tape 465 may be located proximate to the location of the opening 605 in the back cover 240 and proximate to the opening 610 in the interlayer 235. As described below, the free ends and loop 480 may facilitate connection to a cord plate 250 and facilitate in-process evaluation and conditioning of the module 100, 200, 300.

The portions of insulating tape (410, 415, 420, 455, 460, 470) serve at least two important functions. First, for example, the portions of insulating tape electrically insulate: (1) the portions of conductive tape (425, 430, 435, 465) from the back contact layer 230, (2) the portions of conductive tape from each other (e.g., in FIG. 4C, insulating tape 470 insulates conductive tape 465 from conductive tape 475), and (3) the portions of conductive tape from bus bars (e.g., in FIG. 4A, insulating tape 455 insulates conductive tape 425 from bus bar 445). In particular, the insulating tape may prevent short circuiting. Shorting may be avoided by making the portions of conductive tape (425, 430, 435, 465, 475) narrower than the corresponding portions of insulating tape (410, 415, 420, 455, 460, 470), as shown in FIGS. 4A-4C. Second, the portions of insulating tape (410, 415, 420, 455, 460, 470) bond to the portions of conductive tape (425, 430, 435, 465, 475) due to their adhesive coatings. The adhesive prevents the portions of conductive tape (425, 430, 435, 465, 475) from shifting during manufacturing or during use, thereby preventing the portions of conductive tape from directly contacting the back contact layer 230 and causing a short circuit.

As shown by way of example in FIG. 4A-4C, a plurality of bus bars (440, 445, 450) may be formed adjacent to the portions of conductive tape (425, 430, 435, 465, 475). As shown in FIG. 4A, a first bus bar 440 may be formed adjacent to the first portion of conductive tape 425 and substantially parallel to the plurality of cells 401. A second bus bar 445 may be formed adjacent to the second portion of conductive tape 430 and substantially parallel to the plurality of cells 401. A third bus bar 450 may be formed adjacent to the third portion of conductive tape 435. The bus bars (440, 445, 450) may be constructed from any suitable conductive material. For example, the bus bars may include tin, copper, aluminum, silver, gold, or any other suitable conductive material. As shown by way of example in FIG. 4A, the fourth portion of insulating tape 455 may be formed between the first portion of conductive tape 425 and the second bus bar 445. The fourth portion of insulating tape 455 may serve to prevent the second bus bar 445 from electrically contacting the first portion of conductive tape 425. In module 200 of FIG. 4B, the second bus bar 445 is not included and in module 300 of FIG. 4C, the first bus bar 440 is formed adjacent to the fourth portion of conductive tape 465, the second bus bar 445 is formed adjacent to conductive tape 475 and the third bus bar 450 is formed adjacent to conductive tape 465.

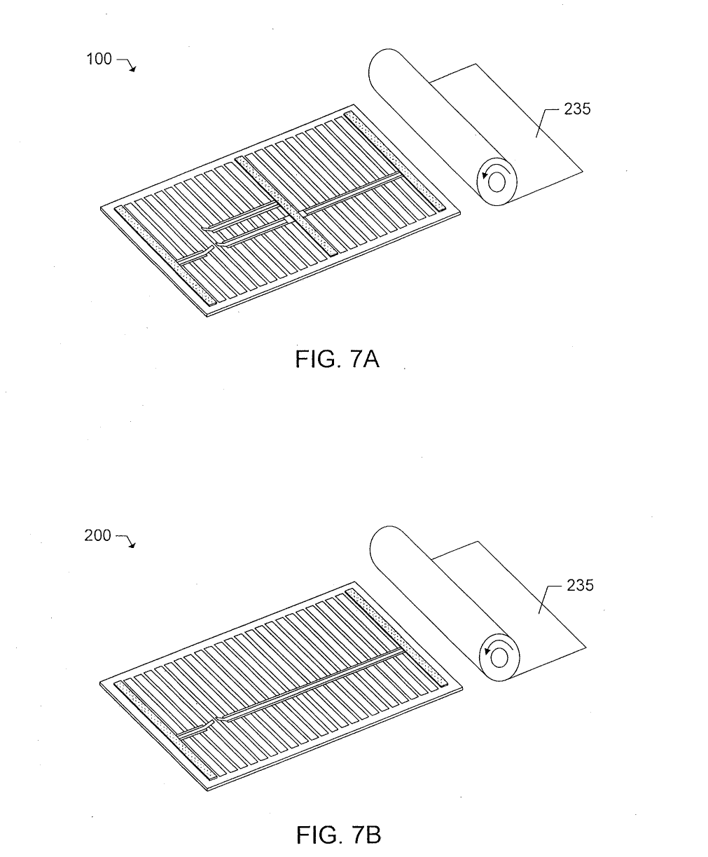

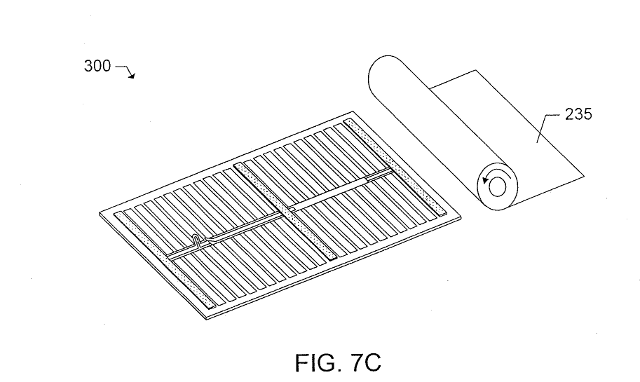

Once the bussing system has been formed, the interlayer 235 may be formed adjacent to the bussing system and back contact layer 230 as shown in the exploded view of FIGS. 6A-6C. The back cover 240 can then be formed adjacent to the interlayer 235 to provide additional protection for the layers within the module 100, 200, 300. The interlayer 235 may be formed using any suitable technique. For example, the interlayer 235 may be added to the module 100, 200, 300 as a sheet as shown in FIGS. 6A-6C, respectively. Alternatively, the interlayer 235 may be added to the module 100, 200, 300 by dispensing the interlayer 235 from a roll, as shown in FIGS. 7A-7C, respectively.

The interlayer shown in FIGS. 6 and 7 is commonly used in PV devices and is constructed from ethylene vinyl acetate (EVA). During the lifespan of a module containing the interlayer as shown in FIGS. 6 and 7, chemical interactions between the interlayer 235 and the portions of conductive tape (e.g., 425, 430, 435, 465, 475) may cause corrosion of the conductive tape. For example, when exposed to high temperatures resulting from high ambient temperatures, incident solar radiation, or other environmental factors, organic acids may form within and upon the EVA. These organics acids may result in corrosion of the portions of conductive tape (e.g., 425, 430, 435, 465, 475). For example, if the portions of conductive tape include tin-plated copper, the organic acids may cause corrosion of the tin-plated copper.

The corroded portions of conductive tape (e.g., 425, 430, 435, 465, 475) may be visible through the back cover 240 of the module 100, 200, 300 if the back cover includes a transparent material, such as glass or polycarbonate. As a result, the corroded portions may detract from the module's appearance. The corroded portions may also decrease the module's performance. For instance, the corrosion may increase the resistance of the portions of conductive tape (e.g., 425, 430, 435, 465, 475) thereby reducing the module's efficiency.

To protect against corrosion of the portions of conductive tape (e.g., 425, 430, 435, 465, 475), it may be desirable to insert one or more corrosion barriers between the portions of conductive tape (e.g., 425, 430, 435, 465, 475) and the interlayer 235. The corrosion barriers may be formed from any suitable electrically insulating material or materials. For example, the corrosion barriers may include polyester or polyethylene terephthalate (PET). In addition, the corrosion barriers may have any suitable shape, such as portions of tape that are slightly wider than the portions of conductive tape to allow for manufacturing and application tolerances. The corrosion barriers may be placed at locations that correspond to the locations of the portions of conductive tape of the respective modules 100, 200, 300.

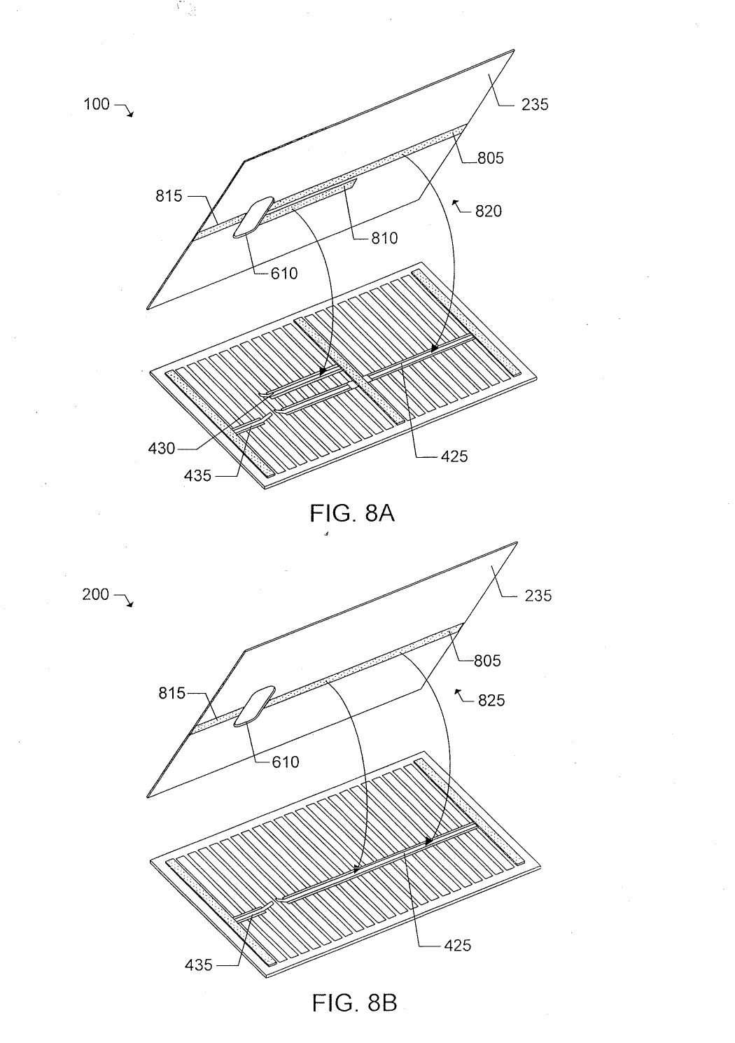

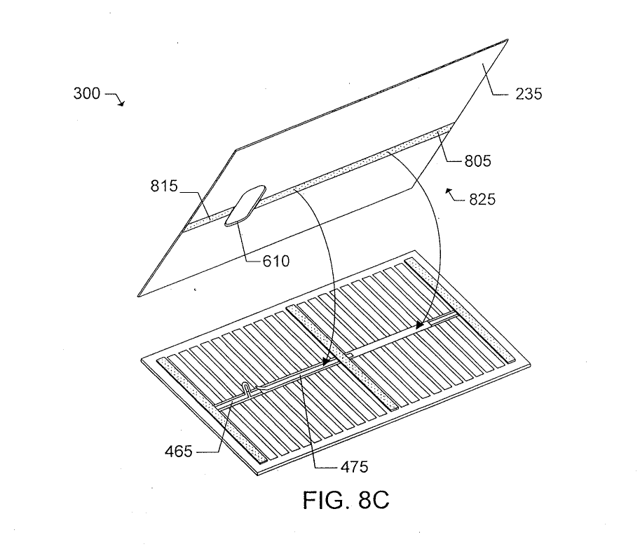

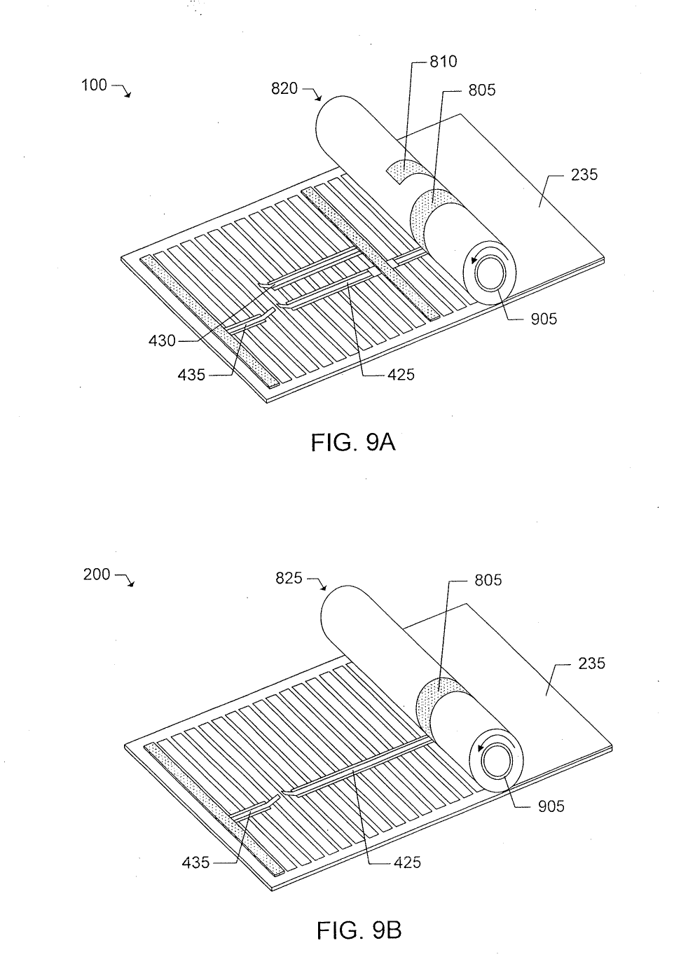

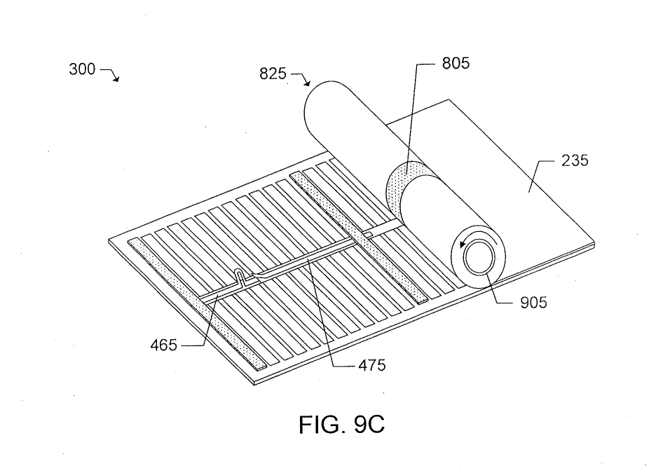

As shown by way of example in FIGS. 8A-8C and 9A-9C, a first corrosion barrier 805 may be formed adjacent to the first portion of conductive tape 425, as shown in FIGS. 8A-8B and 9A-9B, or barrier 805 may be formed adjacent to the fourth portion of conductive tape 465 and the fifth portion of conductive tape 475, as shown in FIGS. 8C and 9C. Similarly, a second corrosion barrier 810 may be formed adjacent to the second portion of conductive tape 430, as shown in FIGS. 8A and 9A, and a third portion of barrier tape 815 may be formed adjacent to a third portion of conductive tape 435, as shown in FIGS. 8A-8B and 9A-9B, or the third portion of barrier tape 815 may be formed adjacent to the fourth portion of conductive tape 465, as shown in FIGS. 8C and 9C. Corrosion barriers 805, 810, 815 can form a mechanical barrier between organic acids formed in interlayer 235 and proximate conductive material, such as conductive tape 425, 430, 435, 465, 475 of the modules 100, 200, 300. Additionally, corrosion barriers 805, 810, 815 can include an acid-neutralizing agent, such as a suitable alkaline material or component or buffering agent.

In some instances, the corrosion barrier may completely eliminate corrosion of the conductive tape caused by organic acids. However, in some instances, the corrosion barrier may not completely prevent all corrosion of the conductive tape. For example, in some instances, even with the corrosion barrier in place, minor corrosion of the conductive tape may still occur. While minor corrosion may not significantly diminish the module's efficiency, it may still detract from the module's appearance. To prevent isolated instances of corrosion from becoming visible through the back cover 240 of the module 100, 200, 300 the corrosion barrier may be constructed from a non-transparent material. For instance, the corrosion barrier may be constructed from a darkly colored translucent material or an opaque material that obscures any corrosion of the conductive tape.

To improve the manufacturing efficiency, it may be desirable to integrate the corrosion barrier into the interlayer prior to assembly of the module 100, 200, 300. For example, during a preceding manufacturing process, the corrosion barrier (e.g., 805, 810, 815) may be integrated into the interlayer 235 to produce a single layer that can be applied to the module in one step similar to the current interlayer application step. By avoiding introducing an additional step to the manufacturing process, it is possible to avoid the additional cost, implementation time, scrap, and downtime associated with adding a step, which requires implementing new equipment.

The corrosion barrier (e.g., 805, 810, 815) may be attached to the interlayer 235 with an adhesive layer. The adhesive layer may include any suitable adhesive such as an acrylic adhesive or heat activated adhesive. The adhesive layer may be applied between the corrosion barrier (e.g., 805, 810, 815) and the interlayer 235. Alternatively, the corrosion barrier may include a backing layer of adhesive. In such instances, the corrosion barrier may be a corrosion barrier tape.

Once the corrosion barrier (e.g., 805, 810, 815) has been attached or integrated into the interlayer 235, the resulting interlayer with one or more corrosion barriers (hereinafter referred to as an “integrated interlayer”) may be prepared for shipping. For instance, sheets of the integrated interlayer may be stacked and boxed for transport. An example of an integrated interlayer 820, 825 is shown in FIGS. 8A-8C in sheet form. Alternatively, the integrated interlayer 820, 825 may be wrapped around a core 905, which may be cylindrical, to form an integrated interlayer 820, 825 roll. During assembly of the module 100, 200, 300 the integrated interlayer 820, 825 may be drawn from the roll, cut to an appropriate size, and placed on the module 100, 200, 300.

It may be necessary to create an opening 610 in the integrated interlayer 820, 825 to permit the free ends of the conductive portions of tape (e.g., 425, 430, 435, 475) or loop 480 of conductive tape 465 to exit the module 100, 200, 300. The opening 610 may be cut after the integrated layer 820, 825 is placed on the module 100, 200, 300. Alternatively, the opening 610 may be cut at any time before, while, or after the one or more corrosion barriers (e.g., 805, 810, 815) are attached to the interlayer 235. For example, the opening 610 may be cut in the interlayer 235 while the corrosion barriers (e.g., 805, 810, 815) are being attached to the interlayer 235.

Accordingly, a layer for use in a PV module may include an interlayer and one or more corrosion barriers adjacent to the interlayer for preventing corrosion of an electrically conductive layer, when the interlayer is installed adjacent to the electrically conductive layer. The corrosion of the electrically conductive layer may be acid-induced. The acid of the acid-induced corrosion may be formed within the interlayer. The interlayer may include a material selected from the group consisting of ethylene vinyl acetate (EVA), polyvinyl butyral (PVB), and thermoplastic polyurethane (TPU). The one or more corrosion barriers may include a material selected from the group consisting of polyester and polyethylene terephthalate (PET). The interlayer may also include an adhesive layer between the interlayer and the one or more corrosion barriers. The adhesive layer may include an acrylic adhesive. Also, the one or more corrosion barriers may be opaque.

In addition, a method for manufacturing an interlayer for a PV module may include forming an interlayer and forming one or more corrosion barriers adjacent to the interlayer using an adhesive. The method may further include wrapping the interlayer around a cylindrical core to facilitate transport and dispensing. The method may also include forming an opening in the interlayer, and the opening may be configured to align with an opening in a back cover of a module upon assembly. The interlayer may include a material selected from the group consisting of ethylene vinyl acetate (EVA), polyvinyl butyral (PVB), and thermoplastic polyurethane (TPU). The one or more corrosion barriers may include a material selected from the group consisting of polyester and polyethylene terephthalate (PET). The adhesive may include an acrylic adhesive, and the one or more corrosion barriers may be opaque.

Furthermore, a PV device may include an interlayer and at least one corrosion barrier adjacent to an electrically conductive layer for preventing the electrically conductive layer from corroding. The electrically conductive layer may be a conductive tape. The at least one corrosion barrier may be aligned with and wider than the conductive tape. The interlayer may include a material selected from the group consisting of ethylene vinyl acetate (EVA), polyvinyl butyral (PVB), and thermoplastic polyurethane (TPU). The at least one corrosion barrier may include a material selected from the group consisting of polyester and polyethylene terephthalate (PET). The conductive tape may include tin-plated copper. The at least one corrosion barrier may be opaque. The at least one corrosion barrier may be attached to the interlayer by an adhesive layer.

Each of the above-described layers may include more than one layer or film. Additionally, each layer can cover all or a portion of the module and/or all or a portion of the layer or substrate underlying the layer. For example, a “layer” can include any amount of any material that contacts all or a portion of a surface. Additionally, any layer can be formed through any suitable deposition technique such as, for example, physical vapor deposition, atomic layer deposition, laser ablation, chemical vapor deposition, close-spaced sublimation, electrodeposition, screen printing, DC pulsed sputtering, RF sputtering, AC sputtering, chemical bath deposition, or vapor transport deposition.

The apparatus and methods disclosed herein may be applied to any type of PV technology including, for example, cadmium telluride, cadmium selenide, amorphous silicon, copper indium (di)selenide (CIS), and copper indium gallium (di)selenide (CIGS). Several of these PV technologies are discussed in U.S. patent application Ser. No. 12/572,172, filed on Oct. 1, 2009, which is incorporated by reference in its entirety. It should be understood that a PV device and components thereof can be configured to allow any suitable absorber material to be incorporated in the PV device.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. It should also be understood that the appended drawings are not necessarily to scale, presenting a somewhat simplified representation of various features and basic principles of the invention.

What is claimed is:

1. A layer for use in a photovoltaic module comprising:
an interlayer; and
one or more corrosion barriers adjacent to the interlayer for preventing corrosion of an electrically conductive layer, when the interlayer is installed adjacent to the electrically conductive layer.

2. The layer of claim 1, wherein the corrosion of the electrically conductive layer is acid-induced.

3. The layer of claim 2, wherein an acid of the acid-induced corrosion is formed within the interlayer.

4. The layer of claim 1, wherein the interlayer comprises a material selected from a group consisting of ethylene vinyl acetate (EVA), polyvinyl butyral (PVB), and thermoplastic polyurethane (TPU).

5. The layer of claim 1, wherein the one or more corrosion barriers comprise a material selected from the group consisting of polyester and polyethylene terephthalate (PET).

6. The layer of claim 1, further comprising an adhesive layer between the interlayer and the one or more corrosion barriers.

7. The layer of claim 6, wherein the adhesive layer comprises an acrylic adhesive.

8. The layer of claim 1, wherein the one or more corrosion barriers are opaque.

9. A method for manufacturing an interlayer for a photovoltaic module, the method comprising:
forming an interlayer; and
forming one or more corrosion barriers adjacent to the interlayer using an adhesive.

10. The method of claim 9, further comprising wrapping the interlayer around a cylindrical core to facilitate transport and dispensing.

11. The method of claim 9, further comprising forming an opening in the interlayer, wherein the opening is configured to align with an opening in a back cover of a module upon assembly.

12. The method of claim 9, wherein the interlayer comprises a material selected from the group consisting of ethylene vinyl acetate (EVA), polyvinyl butyral (PVB), and thermoplastic polyurethane (TPU).

13. A photovoltaic device comprising:
an interlayer; and
at least one corrosion barrier adjacent to an electrically conductive layer for preventing the electrically conductive layer from corroding.

14. The photovoltaic device of claim 13, wherein the electrically conductive layer comprises a conductive tape.

15. The photovoltaic device of claim 14, wherein the at least one corrosion barrier is aligned with and wider than the conductive tape.

16. The photovoltaic device of claim 13, wherein the interlayer comprises a material selected from the group consisting of ethylene vinyl acetate (EVA), polyvinyl butyral (PVB), and thermoplastic polyurethane (TPU).

17. The photovoltaic device of claim 13, wherein the at least one corrosion barrier comprises a material selected from the group consisting of polyester and polyethylene terephthalate (PET).

18. The photovoltaic device of claim 14, wherein the conductive tape comprises tin-plated copper.

19. The photovoltaic device of claim 13, wherein the at least one corrosion barrier is opaque.

20. The photovoltaic device of claim 13, wherein the at least one corrosion barrier is attached to the interlayer by an adhesive layer.
